(19) United States
(12) Patent Application Publication
(10) Pub. No.: US 2024/0312899 A1
(43) Pub. Date: Sep. 19, 2024

(54) SEMICONDUCTOR MODULE, SEMICONDUCTOR DEVICE, AND SEMICONDUCTOR DEVICE MANUFACTURING METHOD

(71) Applicant: FUJI ELECTRIC CO., LTD., Kawasaki-shi (JP)

(72) Inventors: Akito NAKAGOME, Matsumoto-city (JP); Ryoichi KATO, Matsumoto-city (JP); Yuma MURATA, Matsumoto-city (JP)

(73) Assignee: FUJI ELECTRIC CO., LTD., Kawasaki-shi (JP)

(21) Appl. No.: 18/678,584

(22) Filed: May 30, 2024

Related U.S. Application Data
(63) Continuation of application No. PCT/JP2023/017404, filed on May 9, 2023.

(30) Foreign Application Priority Data
Jun. 27, 2022 (JP) 2022-102873

(51) Int. Cl. H01L 23/498

(52) U.S. Cl. CPC H01L 23/49861

(57) ABSTRACT

A semiconductor module includes an insulating sheet, a first terminal, and a second terminal that extend from inside a resin case to the outside. The first terminal is disposed on the first surface of the insulating sheet so as to overlap the insulating sheet in plan view, and includes a first tip portion that is spaced apart from the first surface in a thickness direction. The second terminal is disposed on the second surface of the insulating sheet so as to overlap the insulating sheet and first terminal in plan view, and includes a second tip portion that is spaced apart from the second surface in the thickness direction. The insulating sheet extends from inside the resin case further to the outside than do the first tip portion and the second tip portion.

### CROSS-REFERENCE TO RELATED APPLICATION

This application is a continuation application of International Application PCT/JP2023/017404 filed on May 9, 2023, which designated the U.S., which claims priority to Japanese Patent Application 2022-102873, filed on Jun. 27, 2022, the entire contents of which are incorporated herein by reference.

### BACKGROUND OF THE INVENTION

### 1. Field of the Invention

The embodiments discussed herein relate to a semiconductor module, a semiconductor device, and a semiconductor device manufacturing method.

### 2. Background of the Related Art

For example, a semiconductor module having a power conversion function includes therein a power device. As such a power device, an insulated gate bipolar transistor (IGBT), a metal-oxide-semiconductor field-effect transistor (MOSFET), or another is used. A capacitor may be connected to the semiconductor module in order to stabilize a direct current voltage to be applied.

For such a semiconductor module that is connected to a capacitor, there is known a technique of providing the following terminal portions in the semiconductor module. More specifically, there is known a technique in which, as each terminal portion of the semiconductor module, a multilayer terminal portion is formed by sequentially stacking a first power terminal, an insulating sheet, and a second power terminal in such a manner that a part of the first power terminal is exposed from the insulating sheet and that the second power terminal is located on the insulating sheet with a terrace portion of the insulating sheet between the part of the first power terminal and the second power terminal (Japanese Laid-open Patent Publication No. 2021-106235). A first connection terminal and second connection terminal of the capacitor are respectively bonded by laser welding to the first power terminal exposed from the insulating sheet and the second power terminal provided on the insulating sheet in this multilayer terminal portion.

Further, for a semiconductor module that has a first main terminal and second main terminal that are respectively continuous from a first conductive member and second conductive member arranged with a semiconductor element sandwiched therebetween and extend to the outside of a sealing resin body, there is known a technique in which a first bus bar and second bus bar, which are arranged with an insulation member therebetween, are connected respectively to exposed portions of the first main terminal and second main terminal that are formed on the same side or different sides of the first main terminal and second main terminal depending on the locations of the first main terminal and second main terminal with respect to the sealing resin body (Japanese Laid-open Patent Publication No. 2020-150019).

Still further, there is known a technique in which an insulating member disposed between a first input terminal and second input terminal of a semiconductor device is inserted in the gap between a pair of separate portions formed in an insulator disposed between a first supply terminal and second supply terminal of a bus bar, the first supply terminal and second supply terminal are respectively placed on the external portions of the first input terminal and second input terminal, and the first supply terminal and second supply terminal are conductively bonded respectively to the first input terminal and second input terminal by laser welding (International Publication Pamphlet No. 2019/239771 and International Publication Pamphlet No. 2020/045263).

Still further, there is known a technique in which a positive power terminal and negative power terminal of a semiconductor module, which respectively have power terminal protruding portions that are disposed so as not to overlap each other when viewed in one direction, are connected to a positive bus bar terminal and negative bus bar terminal of a capacitor, which respectively have a positive terminal protruding portion and negative terminal protruding portion that are disposed so as not to overlap each other when viewed in the one direction (Japanese Laid-open Patent Publication No. 2018-67990). In this technique, the positive terminal protruding portion and negative terminal protruding portion do not overlap an insulating member disposed between the positive bus bar terminal and the negative bus bar terminal in the capacitor, the positive power terminal and negative power terminal of the semiconductor module are respectively disposed on the outer sides of the positive terminal protruding portion and negative terminal protruding portion, the positive terminal protruding portion and positive power terminal are welded to each other at the upper ends or facing surfaces thereof, and the negative terminal protruding portion and negative power terminal are welded to each other at the upper ends or facing surfaces thereof.

Still further, there is known a technique in which a semiconductor element bonded to one conductive substrate and another conductive substrate are conductively connected to each other with a lead member. For this technique, there are known a technique in which the lead member bonded to the semiconductor element via a lead bonding layer is bonded to the other conductive substrate by laser welding and a technique in which a metal plate disposed on the semiconductor element is bonded to the lead member by laser welding (International Publication Pamphlet No. 2020/071185 and International Publication Pamphlet No. 2020/179369).

By the way, consider the case where the terminal portion of a semiconductor module to which a capacitor is connected has a multilayer structure in which a positive terminal and a negative terminal sandwich an insulating sheet therebetween. If a connecting member is placed on a terminal disposed directly on the insulating sheet and heat is applied by laser irradiation or the like from the connecting member side for the welding, the heat generated during the welding may damage the insulating sheet disposed directly under the terminal. The damage in the insulating sheet may deteriorate the original insulation performance and thus decrease the withstand voltage.

### SUMMARY OF THE INVENTION

According to an aspect, there is provided a semiconductor module, including: a resin case; an insulating sheet having a first surface and a second surface opposite to the first surface, the insulating sheet extending from inside the resin case to outside; a first terminal extending from inside the resin case to the outside, the first terminal being disposed on the first surface of the insulating sheet, except for a tip portion thereof that is spaced apart from the first surface in a thickness direction perpendicular to the first surface, the first terminal overlapping the insulating sheet in a plan view of the semiconductor module, the tip portion of the first terminal being a first tip portion; and a second terminal extending from inside the resin case to the outside, the second terminal being disposed on the second surface of the insulating sheet, except for a tip portion thereof that is spaced apart from the second surface in the thickness direction, the second terminal overlapping the insulating sheet and the first terminal in the plan view, the tip portion of the second terminal being a second tip portion, wherein the insulating sheet extends further outside than the first tip portion and the second tip portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view for describing an example of a semiconductor device;

FIG. 2 is a view for describing an example of the connecting part between a semiconductor module and a capacitor;

FIGS. 3A to 3C are views for describing how to weld a connecting member to a first terminal of a semiconductor module;

FIGS. 4A and 4B are views for describing an example of a semiconductor module according to a first embodiment;

FIG. 5 is a view for describing an example of a semiconductor device according to the first embodiment;

FIGS. 6A and 6B are views for describing an example of a semiconductor module according to a second embodiment;

FIG. 7 is a view for describing an example of a semiconductor device according to the second embodiment;

FIGS. 8A and 8B are views for describing examples of a semiconductor module according to a third embodiment; and

FIG. 9 is a view for describing an example of a semiconductor device manufacturing method according to a fourth embodiment.

### DETAILED DESCRIPTION OF THE INVENTION

First, an example of a semiconductor device including a semiconductor module and a capacitor will be described.

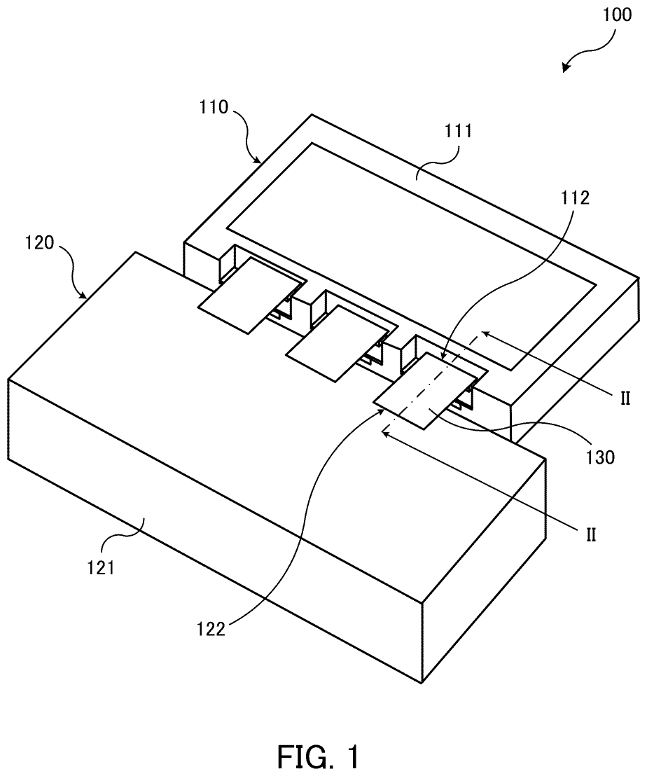

FIG. 1 is a view for describing an example of a semiconductor device. FIG. 1 is a schematic perspective view illustrating a main part of the example semiconductor device.

The semiconductor device 100 illustrated in FIG. 1 includes a semiconductor module 110, a capacitor 120, and connecting members 130 connecting the semiconductor module 110 and the capacitor 120 to each other.

The semiconductor module 110 includes a resin case 111. The resin case 111 has a frame-shaped portion (frame portion). The resin case 111 may further has a cover to cover an inner space surrounded by the frame portion. The resin case 111 may be made of a polyphenylene sulfide resin or another. Inside the resin case 111, or in the inner space surrounded by its frame portion, an insulated circuit substrate, and semiconductor elements and others mounted on the insulated circuit substrate are accommodated.

For example, as the insulated circuit substrate, a substrate formed by forming a conductive layer having a predetermined pattern on both principal surfaces of a ceramic substrate is used. As the ceramic substrate, a substrate made of alumina, composite ceramics containing alumina as a main component, aluminum nitride, silicon nitride, or another material is used. For the conductive layer, a metal such as copper or aluminum is used. As the insulated circuit substrate, a direct copper bonding (DCB) substrate, an active metal brazed (AMB) substrate, or another may be used.

Examples of a semiconductor element mounted on the insulated circuit substrate include an IGBT, a MOSFET, and others. Other examples of the semiconductor element include a diode such as a free-wheeling diode (FWD) and a Schottky barrier diode (SBD). Such a diode may be integrated with an IGBT or MOSFET. Furthermore, components to be connected to the semiconductor element may be mounted on the insulated circuit substrate.

At one side of the resin case 111 of the semiconductor module 110, which accommodates the insulated circuit substrate, and the semiconductor elements and others mounted on the insulated circuit substrate, terminal structure portions 112 are provided, which are connected to the accommodated insulated circuit substrate, semiconductor elements, and others and are used to connect the semiconductor module 110 to the capacitor 120 provided external to the semiconductor module 110. Here, the semiconductor module 110 illustrated as an example has three terminal structure portions 112 provided at the one side of the resin case 111.

The capacitor 120 includes a resin case 121. The resin case 121 is made of a polyphenylene sulfide resin or another. A capacitor element is accommodated in the resin case 121. At one side of the resin case 121, terminal structure portions 122 are provided, which are connected to the accommodated capacitor element and are used to connect the capacitor 120 to the semiconductor module 110 provided external to the capacitor 120. Here, the capacitor 120 illustrated as an example has three terminal structure portions 122 provided at the one side of the resin case 121.

The semiconductor module 110 and the capacitor 120 are disposed such that their terminal structure portions 112 and terminal structure portions 122 face each other, and each terminal structure portion 112 and its corresponding terminal structure portion 122 are connected to each other with a connecting member 130 such as a bus bar. For example, the semiconductor device 100 is implemented by connecting the semiconductor module 110 and the capacitor 120 to each other in this manner. In the semiconductor device 100, circuits having predetermined functions, such as a power conversion circuit and an inverter circuit, are formed with the insulated circuit substrate and the semiconductor elements and others mounted on the insulated circuit substrate provided in the semiconductor module 110 and the capacitor element provided in the capacitor 120.

The connecting part between the semiconductor module 110 and the capacitor 120 in the semiconductor device 100 configured as described above will now be described.

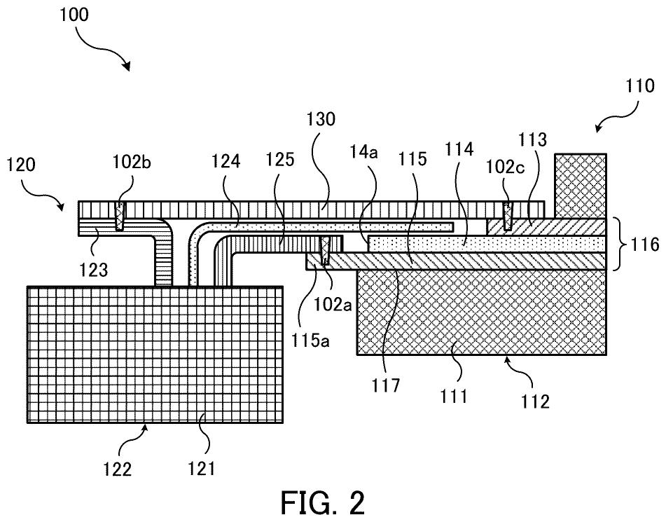

FIG. 2 is a view for describing an example of the connecting part between a semiconductor module and a capacitor. FIG. 2 is a schematic sectional view taken along a line II-II of FIG. 1.

For example, as illustrated in FIG. 2, a terminal structure portion 112 that includes a multilayer structure 116 formed of a first terminal 113, an insulating sheet 114, and a second terminal 115 is provided on the resin case 111 of the semiconductor module 110. For example, the first terminal 113 serves as the negative electrode (N) terminal of the semiconductor module 110, and the second terminal 115 serves as the positive electrode (P) terminal of the semiconductor module 110. The first terminal 113 and second terminal 115 are connected to the insulated circuit substrate accommodated in the resin case 111 or respectively to the negative electrode and positive electrode of a semiconductor element or a component connected thereto accommodated in the resin case 111. The first terminal 113, insulating sheet 114, and second terminal 115 are stacked in such a manner that the insulating sheet 114 is interposed between the first terminal 113 and the second terminal 115. The first terminal 113 and second terminal 115 are made of a metal such as copper or aluminum. The insulating sheet 114 is made of a resin material such as an aramid resin, a polyamide resin, a fluororesin, or a polyimide resin.

The multilayer structure 116 formed of the first terminal 113, insulating sheet 114, and second terminal 115 penetrates through a part of the resin case 111 and is placed on a terrace portion 117 formed in the resin case 111. The multilayer structure 116 is placed on the terrace portion 117 in such a manner that the first terminal 113, insulating sheet 114, and second terminal 115 are stacked in a stepped form. For example, a tip portion 115a of the second terminal 115 located closest to the terrace portion 117 extends to the outside of the resin case 111.

For example, as illustrated in FIG. 2, a terminal structure portion 122 that includes a third terminal 123, an insulating sheet 124, and a fourth terminal 125 is provided on the resin case 121 of the capacitor 120 that is connected to the semiconductor module 110. For example, the third terminal 123 serves as the N terminal of the capacitor 120, and the fourth terminal 125 serves as the P terminal of the capacitor 120. The third terminal 123 and fourth terminal 125 are made of a metal such as copper or aluminum. The insulating sheet 124 is made of a resin material such as an aramid resin, a polyamide resin, a fluororesin, or a polyimide resin.

For example, as illustrated in FIG. 2, the third terminal 123 has one end connected to the resin case 121 and is bent so that the other end thereof extends toward the inner side of the resin case 121. The fourth terminal 125 is disposed outside the third terminal 123 on the resin case 121, and has one end connected to the resin case 121 and is bent so that the other end thereof extends to the outer side of the resin case 121. The insulating sheet 124 has one end connected to the resin case 121 at a position between the third terminal 123 and the fourth terminal 125, and has flexibility so as to be bent toward the fourth terminal 125. The insulating sheet 124 has such a size that it is able to cover the fourth terminal 125 when bent toward the fourth terminal 125.

The semiconductor module 110 and the capacitor 120 are arranged such that the terminal structure portion 112 of the resin case 111 and the terminal structure portion 122 of the resin case 121 face each other. Then, the tip portion 115a of the second terminal 115 of the semiconductor module 110 exposed from the insulating sheet 114 is connected to the fourth terminal 125 of the capacitor 120.

The second terminal 115 of the semiconductor module 110 and the fourth terminal 125 of the capacitor 120 are connected by, for example, laser welding. Alternatively, another technique such as ultrasonic welding or friction stir welding may be employed to connect the second terminal 115 of the semiconductor module 110 to the fourth terminal 125 of the capacitor 120. The fourth terminal 125 of the capacitor 120 is placed on the second terminal 115 of the semiconductor module 110, and heat is applied by laser irradiation or another from the side where the fourth terminal 125 is located, so that the fourth terminal 125 and the second terminal 115 are melt and solidified at a welding area 102a and are thereby welded to each other.

After the second terminal 115 of the semiconductor module 110 and the fourth terminal 125 of the capacitor 120 are connected to each other, the insulating sheet 124 of the capacitor 120 is bent toward the connecting part between the second terminal 115 and the fourth terminal 125. By bending the insulating sheet 124 of the capacitor 120 in this manner, the fourth terminal 125, the tip portion 115a of the second terminal 115 connected thereto, and a part of the insulating sheet 114 are covered with the bent insulating sheet 124.

After the insulating sheet 124 of the capacitor 120 is bent, the first terminal 113 of the semiconductor module 110 and the third terminal 123 of the capacitor 120 are connected to each other with a connecting member 130 such as a bus bar. The connecting member 130 is made of a metal such as copper or aluminum. The connecting member 130 is placed such as to lie over the insulating sheet 124 of the capacitor 120, which is provided to cover the connecting part between the second terminal 115 of the semiconductor module 110 and the fourth terminal 125 of the capacitor 120 and the insulating sheet 114 of the semiconductor module 110, so that the connecting member 130 is connected to the first terminal 113 of the semiconductor module 110 and to the third terminal 123 of the capacitor 120.

The connecting member 130 is connected to the first terminal 113 of the semiconductor module 110 and to the third terminal 123 of the capacitor 120 by, for example, laser welding. Alternatively, another technique such as ultrasonic welding or friction stir welding may be employed to connect the connecting member 130 to the first terminal 113 of the semiconductor module 110 and to the third terminal 123 of the capacitor 120. The connecting member 130 is placed on the first terminal 113 of the semiconductor module 110 and the third terminal 123 of the capacitor 120, and heat is applied by laser irradiation or another from the side where the connecting member 130 is located. Thereby, the connecting member 130, third terminal 123, and first terminal 113 are melt and solidified at a welding area 102b and a welding area 102c, so that the connecting member 130 is welded to the third terminal 123 and to the first terminal 113.

For example, by connecting the terminal structure portion 112 and the terminal structure portion 122 to each other with the connecting member 130 as described above, the semiconductor module 110 and the capacitor 120 are connected to each other.

The following describes the welding of the first terminal 113 of the semiconductor module 110 and the connecting member 130.

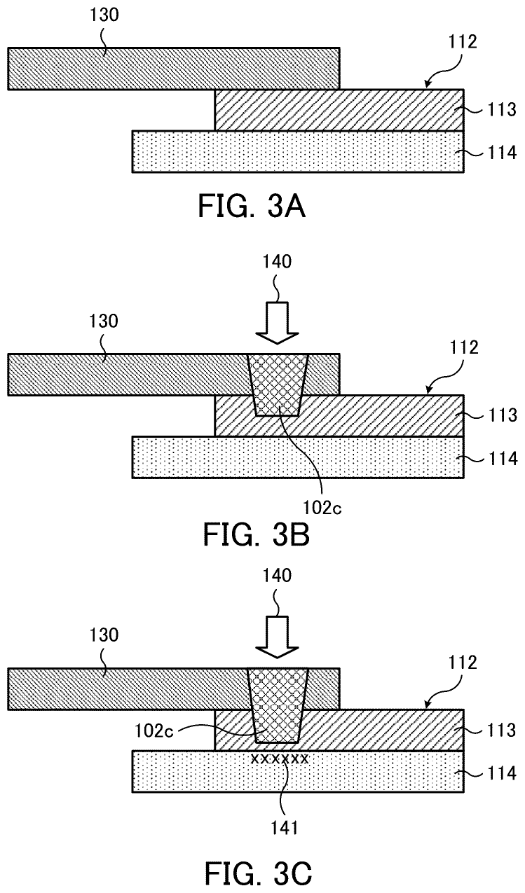

FIGS. 3A to 3C are views for describing how to weld a connecting member to a first terminal of a semiconductor module. FIGS. 3A to 3C are schematic sectional views illustrating an example of a welding step.

FIGS. 3A to 3C merely illustrate the insulating sheet 114 and first terminal 113 in the terminal structure portion 112 of the semiconductor module 110 and the connecting member 130, for convenience. For example, in welding the connecting member 130 to the first terminal 113, the connecting member 130 is first placed on the first terminal 113, as illustrated in FIG. 3A. Then, as illustrated in FIG. 3B, heat 140 is applied by laser irradiation or another from the side where the connecting member 130 is located, so that the connecting member 130 and the first terminal 113 placed under the connecting member 130 are melt and solidified at a welding area 102c and are thereby welded to each other.

Note, however, that the heat 140 by the laser irradiation or another may cause overheating during the welding, which may lead to excessive melting of the connecting member 130 and first terminal 113. If this happens, the insulating sheet 114 undergoes thermal stress, and therefore a damage 141 may occur in the insulating sheet 114, as illustrated in FIG. 3C. As another possibility, the excessive melting of the first terminal 113 may cause the welding area 102c to penetrate through the first terminal 113 to reach the insulating sheet 114, and therefore a damage 141 may occur in the insulating sheet 114. If such a damage 141 occurs in the insulating sheet 114, the properties of the material at the area with the damage 141 and its surrounding area may change, which may prevent the insulating sheet 114 from maintaining its original insulation performance and accordingly may decrease the withstand voltage.

In view of the foregoing, the configurations that will be described in the following embodiments are employed to reduce the risk of damaging an insulating sheet during the welding of a terminal of a semiconductor module.

### First Embodiment

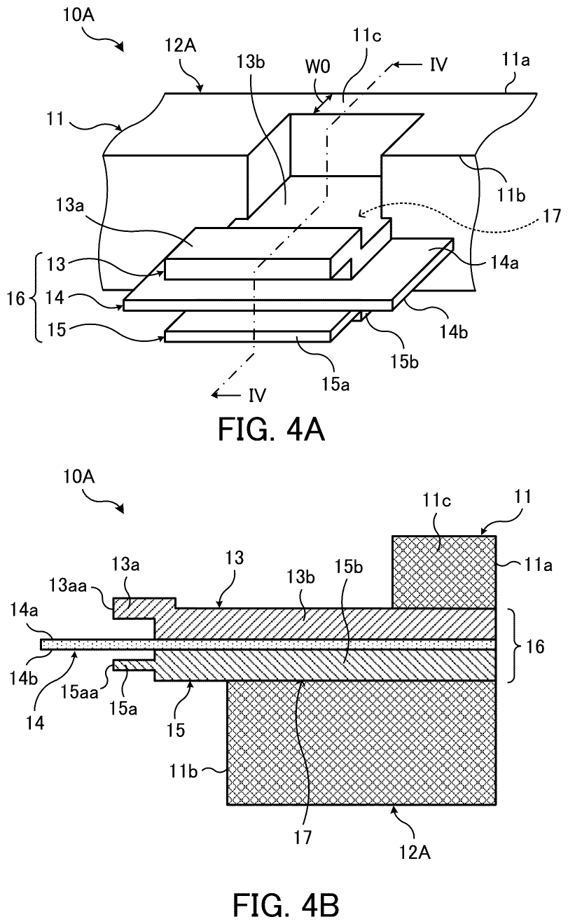

FIGS. 4A and 4B are views for describing an example of a semiconductor module according to a first embodiment. FIG. 4A is a schematic perspective view illustrating a main part of the example semiconductor module. FIG. 4B is a schematic sectional view illustrating the main part of the example semiconductor module. FIG. 4B is a sectional view taken along a line IV-IV of FIG. 4A, as seen in the arrow direction of the line IV-IV.

The semiconductor module 10A illustrated in FIGS. 4A and 4B includes a resin case 11 and a terminal structure portion 12A disposed at one side of the resin case 11.

The resin case 11 of the semiconductor module 10A has a frame portion. The resin case 11 may further have a cover to cover an inner space surrounded by the frame portion. FIGS. 4A and 4B illustrate a part of the one side of the frame portion of the resin case 11. Note that the resin case 11 has an inner edge 11a and an outer edge 11b of the frame portion, and the inner edge 11a faces the inner space surrounded by the frame portion.

The resin case 11 is made of a polyphenylene sulfide resin, for example. Alternatively, the resin case 11 may be made of a polybutylene terephthalate resin, a polybutylene succinate resin, a polyamide resin, an acrylonitrile-butadiene-styrene resin, or another. For example, the resin case 11 is formed by injection molding using such a resin material.

Inside the resin case 11, or in the inner space surrounded by the frame portion of the resin case 11, an insulated circuit substrate, and semiconductor elements and others mounted on the insulated circuit substrate are accommodated. For example, as the insulated circuit substrate, a substrate formed by forming a conductive layer having a predetermined pattern on both principal surfaces of a ceramic substrate is used. As the insulated circuit substrate, a DCB substrate, an AMB substrate, or another may be used. Examples of a semiconductor element mounted on the insulated circuit substrate include an IGBT and a MOSFET. In addition, components that are connected to the semiconductor elements may be mounted on the insulated circuit substrate.

The terminal structure portion 12A is provided at one side of the frame portion of the resin case 11 that accommodates the above insulated circuit substrate, semiconductor elements, and others in the inner space thereof. A plurality of terminal structure portions 12A may be provided at the one side of the resin case 11 of the semiconductor module 10A.

The terminal structure portion 12A includes a multilayer structure 16 formed of a first terminal 13, an insulating sheet 14, and a second terminal 15. For example, the first terminal 13 serves as the N terminal of the semiconductor module 10A, and the second terminal 15 serves as the P terminal of the semiconductor module 10A. The first terminal 13 and second terminal 15 are connected to the insulated circuit substrate accommodated in the resin case 11 or respectively to the negative electrode and positive electrode of a semiconductor element or the like accommodated in the resin case 11. The first terminal 13, insulating sheet 14, and second terminal 15 are stacked in such a manner that the insulating sheet 14 is interposed between the first terminal 13 and the second terminal 15. The multilayer structure 16 formed of the first terminal 13, insulating sheet 14, and second terminal 15 penetrates through a part of the resin case 11 and is placed on a terrace portion 17 formed in the resin case 11. For example, the multilayer structure 16 is pressed against the terrace portion 17 by a pressing portion 11c with a width W0 of the resin case 11. For example, in molding the resin case 11 using a resin material such as a polyphenylene sulfide resin, the terminal structure portion 12A is formed by insert-molding the multilayer structure 16 using the resin material.

The insulating sheet 14 of the terminal structure portion 12A is arranged to extend to the outside of the resin case 11 (beyond the outer edge 11b). The insulating sheet 14 is provided such as to extend from inside the resin case 11 further to the outside than the first terminal 13 (a first tip portion 13a thereof) and the second terminal 15 (a second tip portion 15a thereof). The insulating sheet 14 is made of a resin material such as an aramid resin, a polyamide resin, a fluororesin, or a polyimide resin.

The first terminal 13 of the terminal structure portion 12A is arranged to extend to the outside of the resin case 11 (beyond the outer edge 11b). The first terminal 13 is disposed on the side of the insulating sheet 14 where the first surface 14a is located such as to overlap the insulating sheet 14 in plan view. The first terminal 13 has the first tip portion 13a that is spaced apart from the first surface 14a of the insulating sheet 14. The first terminal 13 has a first extending portion 13b that extends from the first tip portion 13a toward the resin case 11 and that contacts the first surface 14a of the insulating sheet 14. For example, the first terminal 13 is bent between the first extending portion 13b and the first tip portion 13a so that, when the first terminal 13 is arranged such that the first extending portion 13b contacts the first surface 14a of the insulating sheet 14, the first tip portion 13a is spaced apart from the first surface 14a of the insulating sheet 14. The first terminal 13 is made of a metal such as copper or aluminum.

The second terminal 15 of the terminal structure portion 12A is arranged to extend to the outside of the resin case 11 (beyond the outer edge 11b). The second terminal 15 is disposed on the side of the insulating sheet 14 where the second surface 14b opposite to the first surface 14a is located such as to overlap the insulating sheet 14 and the first terminal 13 in plan view. The second terminal 15 has the second tip portion 15a that is spaced apart from the second surface 14b of the insulating sheet 14. The second terminal 15 has a second extending portion 15b that extends from the second tip portion 15a toward the resin case 11 and that contacts the second surface 14b of the insulating sheet 14. For example, in the second terminal 15, the second tip portion 15a is more recessed than the second extending portion 15b so that, when the second terminal 15 is arranged such that the second extending portion 15b contacts the second surface 14b of the insulating sheet 14, the second tip portion 15a is spaced apart from the second surface 14b of the insulating sheet 14. The second terminal 15 is made of a metal such as copper or aluminum.

A part (referred to as a “first portion”) of the first extending portion 13b of the first terminal 13 that is a portion extending from the first tip portion 13a toward the resin case 11, a part (referred to as a “second portion”) of the second extending portion 15b of the second terminal 15 that is a portion extending from the second tip portion 15a toward the resin case 11, and a part (referred to as a “third portion”) of the insulating sheet 14 sandwiched between the first portion and the second portion are placed on the terrace portion 17 formed in the resin case 11. The first portion, second portion, and third portion are pressed against the terrace portion 17 by the pressing portion 11c of the resin case 11.

The semiconductor module 10A configured as described above is connected to a capacitor. As a result, a semiconductor device including the semiconductor module 10A and capacitor is implemented.

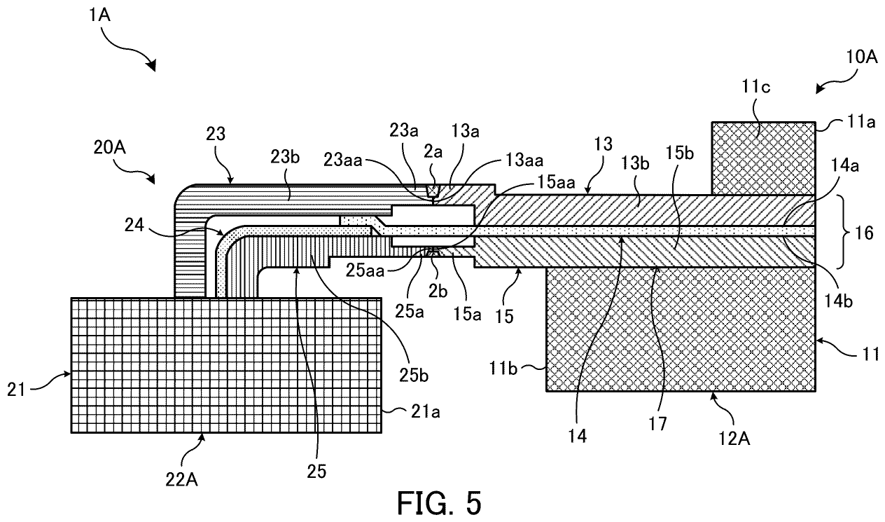

FIG. 5 is a view for describing an example of a semiconductor device according to the first embodiment. FIG. 5 is a schematic sectional view illustrating a main part of the example semiconductor device.

The semiconductor device 1A illustrated in FIG. 5 includes the semiconductor module 10A and a capacitor 20A.

The capacitor 20A includes a resin case 21. The resin case 21 is made of a polyphenylene sulfide resin or another. A capacitor element is accommodated in the resin case 21. At one side of the resin case 21, a terminal structure portion 22A is provided, which is connected to the accommodated capacitor element to connect the capacitor 20A to the semiconductor module 10A provided external to the capacitor 20A. The terminal structure portion 22A of the capacitor 20A is arranged at a position corresponding to the terminal structure portion 12A of the semiconductor module 10A. A plurality of terminal structure portions 22A may be provided at the one side of the resin case 21.

The terminal structure portion 22A of the capacitor 20A includes a third terminal 23, an insulating sheet 24, and a fourth terminal 25. For example, the third terminal 23 serves as the N terminal of the capacitor 20A, and the fourth terminal 25 serves as the P terminal of the capacitor 20A. The third terminal 23 and fourth terminal 25 are connected respectively to the negative electrode and positive electrode of the capacitor element accommodated in the resin case 21. The third terminal 23 and fourth terminal 25 are made of a metal such as copper or aluminum. The insulating sheet 24 is made of a resin material such as an aramid resin, a polyamide resin, a fluororesin, or a polyimide resin.

In the terminal structure portion 22A, the third terminal 23 has one end connected to the resin case 21 and is bent so that the other end thereof extends toward the outside of the resin case 21 (beyond an outer edge 21a thereof). The fourth terminal 25 has one end connected to the resin case 21 and is bent so that the other end thereof extends toward the outside of the resin case 21. The one end of the fourth terminal 25 is located outside the one end of the third terminal 23 on the resin case 21. The insulating sheet 24 has one end connected to the resin case 21 at a position between the one end of the third terminal 23 and the one end of the fourth terminal 25, and has flexibility so as to be bent toward the fourth terminal 25.

The third terminal 23 of the terminal structure portion 22A has a third tip portion 23a. The third tip portion 23a of the third terminal 23 has a third tip surface 23aa that faces a first tip surface 13aa of the first tip portion 13a of the first terminal 13 of the semiconductor module 10A. For example, the third tip surface 23aa of the third tip portion 23a and the first tip surface 13aa of the first tip portion 13a have the same shape. For example, the third tip portion 23a is more recessed than a third extending portion 23b extending from the third tip portion 23a toward the resin case 21.

The fourth terminal 25 of the terminal structure portion 22A has a fourth tip portion 25a. The fourth tip portion 25a of the fourth terminal 25 has a fourth tip surface 25aa that faces a second tip surface 15aa of the second tip portion 15a of the second terminal 15 of the semiconductor module 10A. For example, the fourth tip surface 25aa of the fourth tip portion 25a and the second tip surface 15aa of the second tip portion 15a have the same shape. For example, the fourth tip portion 25a is more recessed than a fourth extending portion 25b extending from the fourth tip portion 25a toward the resin case 21.

In connecting the semiconductor module 10A and the capacitor 20A to each other, the semiconductor module 10A and the capacitor 20A are arranged such that their terminal structure portion 12A and terminal structure portion 22A face each other. At this time, the first tip portion 13a of the first terminal 13 of the semiconductor module 10A and the third tip portion 23a of the third terminal 23 of the capacitor 20A are arranged such that their first tip surface 13aa and third tip surface 23aa contact each other. At the same time, the second tip portion 15a of the second terminal 15 of the semiconductor module 10A and the fourth tip portion 25a of the fourth terminal 25 of the capacitor 20A are arranged such that their second tip surface 15aa and fourth tip surface 25aa contact each other.

At this time, in the semiconductor module 10A, the first tip portion 13a of the first terminal 13 is located on the side of the insulating sheet 14 where the first surface 14a is located, spaced apart from the insulating sheet 14, and the second tip portion 15a of the second terminal 15 is located on the side of the insulating sheet 14 where the second surface 14b is located, spaced apart from the insulating sheet 14. Similarly, in the capacitor 20A, the third tip portion 23a of the third terminal 23, which is to contact the first tip portion 13a, is located on the side of the insulating sheet 14 where the first surface 14a is located, spaced apart from the insulating sheet 14, and the fourth tip portion 25a of the fourth terminal 25, which is to contact the second tip portion 15a, is located on the side of the insulating sheet 14 where the second surface 14b is located, spaced apart from the insulating sheet 14. On the side of the insulating sheet 14 where the first surface 14a is located, the first tip portion 13a and third tip portion 23a are brought into contact with each other in a state of being spaced apart from the first surface 14a. On the side of the insulating sheet 14 where the second surface 14b is located, the second tip portion 15a and fourth tip portion 25a are brought into contact with each other in a state of being spaced apart from the second surface 14b.

Then, heat is applied by, for example, laser irradiation to the contact area where the first tip portion 13a and third tip portion 23a contact each other, from the opposite side (upper side in FIG. 5) of the contact area from the insulating sheet 14. By doing so, the first tip portion 13a and third tip portion 23a are melt and solidified at a first welding area 2a and are thereby welded to each other and a welding portion (2a) is formed. For example, with this technique, the first terminal 13 of the semiconductor module 10A and the third terminal 23 of the capacitor 20A are welded to each other. In this example, the heat is applied by laser irradiation to weld (laser-weld) the first terminal 13 and the third terminal 23 to each other. Alternatively, another technique such as ultrasonic welding or friction stir welding may be employed to apply heat from the opposite side from the insulating sheet 14 in order to weld the first terminal 13 and the third terminal 23 to each other.

In this connection, in the case of the laser welding, a metal plate made of copper, aluminum, or another may be inserted in the space formed between the contact area where the first tip portion 13a and third tip portion 23a contact each other and the insulating sheet 14. Even if there is a gap in the contact area between the first tip portion 13a and the third tip portion 23a, the metal plate is able to prevent the laser from reaching the insulating sheet 14 through the gap, thereby reducing the risk of damaging the insulating sheet 14 due to the laser. In the case of the ultrasonic welding, friction stir welding, or another, the welding may be performed while a predetermined jig is inserted into the space between the contact area of the first tip portion 13a and third tip portion 23a and the insulating sheet 14 and the contact area is pressed with a predetermined tool from the opposite side from the insulating sheet 14.

As is done for the first tip portion 13a and third tip portion 23a that contact each other, heat is applied by, for example, laser irradiation to the contact area where the second tip portion 15a and fourth tip portion 25a contact each other, from the opposite side (lower side in FIG. 5) of the contact area from the insulating sheet 14. By doing so, the second tip portion 15a and fourth tip portion 25a are melted and solidified at a second welding area 2b and are thereby welded to each other and a welding portion (2b) is formed. For example, with this technique, the second terminal 15 of the semiconductor module 10A and the fourth terminal 25 of the capacitor 20A are welded to each other. In this example, the heat is applied by laser irradiation to weld (laser weld) the second terminal 15 and the fourth terminal 25 to each other. Alternatively, another technique such as ultrasonic welding or friction stir welding may be employed to apply heat in order to weld the second terminal 15 and the fourth terminal 25 to each other.

In this connection, in the case of the laser welding, a metal plate made of copper, aluminum, or another may be inserted in the space formed between the contact area where the second tip portion 15a and fourth tip portion 25a contact each other and the insulating sheet 14. Even If there is a gap in the contact area of the second tip portion 15a and the fourth tip portion 25a, the metal plate is able to prevent the laser from reaching the insulating sheet 14 through the gap, thereby reducing the risk of damaging the insulating sheet 14 due to the laser. In the case of the ultrasonic welding, friction stir welding, or another, the welding may be performed while a predetermined jig is inserted into the space between the contact area of the second tip portion 15a and fourth tip portion 25a and the insulating sheet 14 and the contact area is pressed with a predetermined tool from the opposite side from the insulating sheet 14.

Either the welding of the first terminal 13 and third terminal 23 or the welding of the second terminal 15 and fourth terminal 25 may be performed first, or both of them may be performed simultaneously.

The semiconductor module 10A and capacitor 20A are connected to each other as described above, so that the semiconductor device 1A as illustrated in FIG. 5 is obtained.

As described above, the semiconductor module 10A has the following configuration: the insulating sheet 14, the first terminal 13, and the second terminal 15 all extend to the outside of the resin case 11, the first tip portion 13a of the first terminal 13 is spaced apart from the first surface 14a of the insulating sheet 14, and the second tip portion 15a of the second terminal 15 is spaced apart from the second surface 14b of the insulating sheet 14. In the capacitor 20A, the third terminal 23 with the third tip portion 23a and the fourth terminal 25 with the fourth tip portion 25a are arranged so that the third tip portion 23a and fourth tip portion 25a respectively contact the first tip portion 13a of the first terminal 13 and the second tip portion 15a of the second terminal 15 in the semiconductor module 10A. The first tip portion 13a and third tip portion 23a that contact each other are then welded to each other by heat applied from the opposite side from the insulating sheet 14, and the second tip portion 15a and fourth tip portion 25a that contact each other are welded to each other by heat applied from the opposite side from the insulating sheet 14.

At this time, the first welding area 2a of the first tip portion 13a and third tip portion 23a is spaced apart from the insulating sheet 14, and the second welding area 2b of the second tip portion 15a and fourth tip portion 25a is spaced apart from the insulating sheet 14. Therefore, heat generated during the formation of the first welding area 2a and second welding area 2b is prevented from being transferred directly to the insulating sheet 14. This reduces the risk of damaging the insulating sheet 14 due to the heat during the welding. The reduction in the risk of damaging the insulating sheet 14 leads to preventing changes in the properties of the material of the insulating sheet 14, which prevents a deterioration in the insulation performance and accordingly a decrease in the withstand voltage. Thus, the above-described technique makes it possible to implement the high-performance, high-quality semiconductor device 1A.

Note that the shapes of the first terminal 13 and second terminal 15 illustrated in FIGS. 4 and 5, as well as the shapes of the third terminal 23 and fourth terminal 25 illustrated in FIG. 5, are not limited to those in the above-described example. As long as the first tip surface 13aa of the first tip portion 13a and the third tip surface 23aa of the third tip portion 23a are allowed to contact each other and be welded to each other in a state of being spaced apart from the insulating sheet 14 and also as long as the second tip surface 15aa of the second tip portion 15a and the fourth tip surface 25aa of the fourth tip portion 25a are allowed to contact each other and be welded to each other in a state of being spaced apart from the insulating sheet 14, various shapes may be employed for the first terminal 13 and second terminal 15 and for the third terminal 23 and fourth terminal 25.

### Second Embodiment

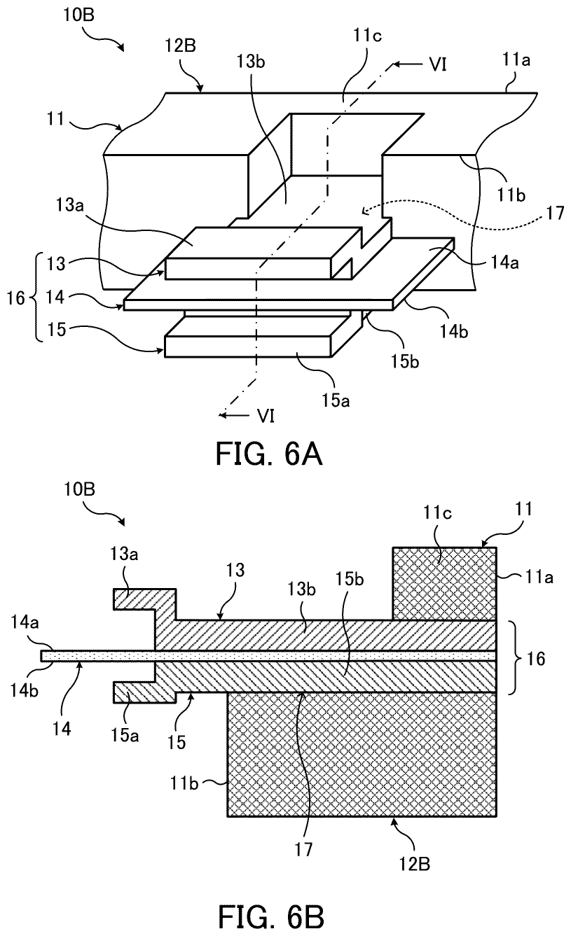

FIGS. 6A and 6B are views for describing an example of a semiconductor module according to a second embodiment. FIG. 6A is a schematic perspective view illustrating a main part of the example semiconductor module. FIG. 6B is a schematic sectional view illustrating the main part of the example semiconductor module. FIG. 6B is a sectional view taken along a line VI-VI of FIG. 6A, as seen in the arrow direction of the line VI-VI.

The semiconductor module 10B illustrated in FIGS. 6A and 6B includes a terminal structure portion 12B provided at one side of a resin case 11 (a frame portion thereof).

The terminal structure portion 12B includes a multilayer structure 16 formed of a first terminal 13, an insulating sheet 14, and a second terminal 15. For example, the first terminal 13 serves as the N terminal of the semiconductor module 10B, and the second terminal 15 serves as the P terminal of the semiconductor module 10B. The first terminal 13 and second terminal 15 are connected to an insulated circuit substrate accommodated in the resin case 11 or respectively to the negative electrode and positive electrode of a semiconductor element or the like accommodated in the resin case 11. The first terminal 13, insulating sheet 14, and second terminal 15 are stacked in such a manner that the insulating sheet 14 is interposed between the first terminal 13 and the second terminal 15. The multilayer structure 16 formed of the first terminal 13, insulating sheet 14, and second terminal 15 penetrates through a part of the resin case 11, and is placed on a terrace portion 17 formed in the resin case 11. For example, the multilayer structure 16 is pressed against the terrace portion 17 by a pressing portion 11c of the resin case 11.

The insulating sheet 14 of the terminal structure portion 12B is arranged to extend to the outside of the resin case 11 (beyond an outer edge 11b thereof). The insulating sheet 14 is arranged to extend from inside the resin case 11 further to the outside than the first terminal 13 (a first tip portion 13a thereof) and the second terminal 15 (a second tip portion 15a thereof).

The first terminal 13 of the terminal structure portion 12B is arranged to extend to the outside of the resin case 11 (beyond the outer edge 11b). The first terminal 13 is disposed on the side of the insulating sheet 14 where a first surface 14a thereof is located such as to overlap the insulating sheet 14 in plan view. The first terminal 13 has the first tip portion 13a that is spaced apart from the first surface 14a of the insulating sheet 14. The first terminal 13 has a first extending portion 13b that extends from the first tip portion 13a toward the resin case 11 and that contacts the first surface 14a of the insulating sheet 14. For example, the first terminal 13 is bent between the first extending portion 13b and the first tip portion 13a so that, when the first terminal 13 is arranged such that the first extending portion 13b contacts the first surface 14a of the insulating sheet 14, the first tip portion 13a is spaced apart from the first surface 14a of the insulating sheet 14.

The second terminal 15 of the terminal structure portion 12B is arranged to extend to the outside of the resin case 11 (beyond the outer edge 11b). The second terminal 15 is disposed on the side of the insulating sheet 14 where the second surface 14b is located such as to overlap the insulating sheet 14 and first terminal 13 in plan view. The second terminal 15 has the second tip portion 15a that is spaced apart from the second surface 14b of the insulating sheet 14. The second terminal 15 has a second extending portion 15b that extends from the second tip portion 15a toward the resin case 11 and that contacts the second surface 14b of the insulating sheet 14. For example, the second terminal 15 is bent between the second extending portion 15b and the second tip portion 15a so that, when the second terminal 15 is arranged such that the second extending portion 15b contacts the second surface 14b of the insulating sheet 14, the second tip portion 15a is spaced apart from the second surface 14b of the insulating sheet 14.

A part (referred to as a “first portion”) of the first extending portion 13b of the first terminal 13 that is a portion extending from the first tip portion 13a toward the resin case 11, a part (referred to as a “second portion”) of the second extending portion 15b of the second terminal 15 that is a portion extending from the second tip portion 15a toward the resin case 11, and a part (referred to as a “third portion”) of the insulating sheet 14 sandwiched between the first portion and the second portion are placed on the terrace portion 17 formed in the resin case 11. The first portion, second portion, and third portion are pressed against the terrace portion 17 by the pressing portion 11c of the resin case 11.

The semiconductor module 10B differs from the semiconductor module 10A described earlier in the first embodiment in that the semiconductor module 10B includes the terminal structure portion 12B with the first terminal 13 and second terminal 15 whose tip portions have different shapes from those described in the first embodiment.

The semiconductor module 10B configured as described above is connected to a capacitor, so that a semiconductor device is obtained.

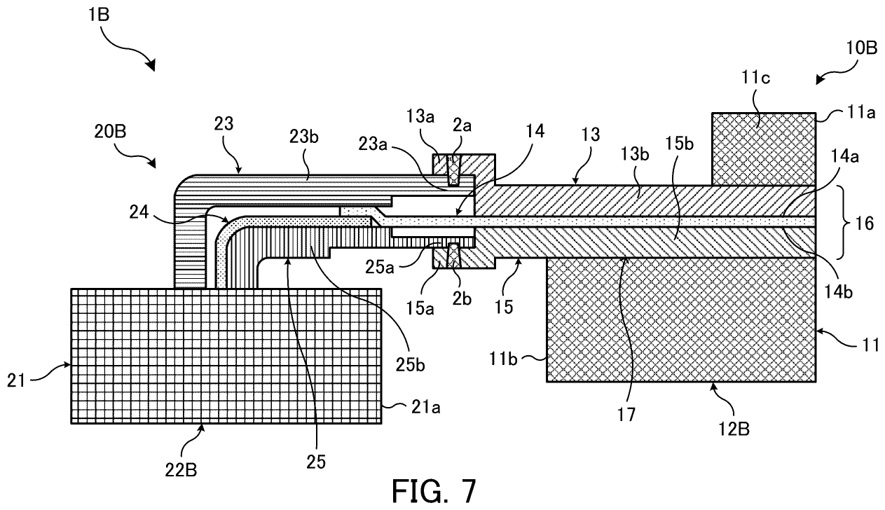

FIG. 7 is a view for describing an example of a semiconductor device according to the second embodiment. FIG. 7 is a schematic sectional view illustrating a main part of the example semiconductor device.

The semiconductor device 1B illustrated in FIG. 7 includes the semiconductor module 10B and a capacitor 20B.

The capacitor 20B includes a resin case 21 that accommodates therein a capacitor element. At one side of the resin case 21, a terminal structure portion 22B is provided, which is connected to the accommodated capacitor element and is used to connect the capacitor 20B to the semiconductor module 10B provided external to the capacitor 20B. The terminal structure portion 22B of the capacitor 20B is arranged at a position corresponding to the terminal structure portion 12B of the semiconductor module 10B. A plurality of terminal structure portions 22B may be provided at the one side of the resin case 21.

The terminal structure portion 22B of the capacitor 20B includes a third terminal 23, an insulating sheet 24, and a fourth terminal 25. For example, the third terminal 23 serves as the N terminal of the capacitor 20B, and the fourth terminal 25 serves as the P terminal of the capacitor 20B. The third terminal 23 and fourth terminal 25 are connected respectively to the negative electrode and positive electrode of the capacitor element accommodated in the resin case 21.

In the terminal structure portion 22B, the third terminal 23 has one end connected to the resin case 21, and is bent so that the other end thereof extends toward the outside of the resin case 21 (beyond an outer edge 21a thereof). The fourth terminal 25 has one end connected to the resin case 21 and is bent so that the other end thereof extends to the outside of the resin case 21. The one end of the fourth terminal 25 is located outside the one end of the third terminal 23 on the resin case 21. The insulating sheet 24 has one end connected to the resin case 21 at a position between the one end of the third terminal 23 and the one end of the fourth terminal 25, and has flexibility so as to be bent toward the fourth terminal 25.

The third terminal 23 of the terminal structure portion 22B has a third tip portion 23a and a third extending portion 23b extending from the third tip portion 23a toward the resin case 21. The third tip portion 23a is more recessed than the third extending portion 23b. The fourth terminal 25 of the terminal structure portion 22B has a fourth tip portion 25a and a fourth extending portion 25b extending from the fourth tip portion 25a toward the resin case 21. The fourth tip portion 25a is more recessed than the fourth extending portion 25b. For example, the third terminal 23 and fourth terminal 25 of the terminal structure portion 22B have shapes like those in which the third tip portion 23a of the third terminal 23 and the fourth tip portion 25a of the fourth terminal 25 in the terminal structure portion 22A described earlier in the first embodiment are further extended to the outside of the resin case 21.

In connecting the semiconductor module 10B and the capacitor 20B to each other, the semiconductor module 10B and the capacitor 20B are arranged such that their terminal structure portion 12B and terminal structure portion 22B face each other. At this time, the third tip portion 23a of the third terminal 23 of the capacitor 20B is inserted and arranged in the space between the first surface 14a of the insulating sheet 14 and the first tip portion 13a of the first terminal 13 spaced apart from the first surface 14a in the semiconductor module 10B. At the same time, the fourth tip portion 25a of the fourth terminal 25 of the capacitor 20B is inserted and arranged in the space between the second surface 14b of the insulating sheet 14 and the second tip portion 15a of the second terminal 15 spaced apart from the second surface 14b in the semiconductor module 10B.

The third terminal 23 and fourth terminal 25 are provided in advance in the capacitor 20B so that, when the third tip portion 23a and fourth tip portion 25a are arranged respectively between the first surface 14a of the insulating sheet 14 and the first tip portion 13a and between the second surface 14b and the second tip portion 15a as described above, the third tip portion 23a contacts the first tip portion 13a and the fourth tip portion 25a contacts the second tip portion 15a. Alternatively, the first terminal 13 and second terminal 15 are provided in advance in the semiconductor module 10B so that, when the third tip portion 23a and fourth tip portion 25a are arranged respectively between the first surface 14a of the insulating sheet 14 and the first tip portion 13a and between the second surface 14b and the second tip portion 15a, the first tip portion 13a contacts the third tip portion 23a and the second tip portion 15a contacts the fourth tip portion 25a.

The third tip portion 23a is arranged between the first surface 14a and the first tip portion 13a in a state of being spaced apart from the first surface 14a of the insulating sheet 14 and contacting the first tip portion 13a of the first terminal 13. The fourth tip portion 25a is arranged between the second surface 14b and the second tip portion 15a in a state of being spaced apart from the second surface 14b of the insulating sheet 14 and contacting the second tip portion 15a of the second terminal 15.

Then, heat is applied by, for example, laser irradiation to the first tip portion 13a arranged over the insulating sheet 14 with the third tip portion 23a therebetween, from the side where the first tip portion 13a is located (from the upper side in FIG. 7). As a result, the first tip portion 13a and third tip portion 23a are melted and solidified at a first welding area 2a and are thereby welded to each other. For example, with this technique, the first terminal 13 of the semiconductor module 10B and the third terminal 23 of the capacitor 20B are welded to each other. In this example, the heat is applied by laser irradiation to weld (laser weld) the first terminal 13 and the third terminal 23 to each other. Alternatively, another technique such as ultrasonic welding or friction stir welding may be employed to apply heat from the side where the first tip portion 13a is located in order to weld the first terminal 13 and the third terminal 23 to each other.

In this connection, in the case of the laser welding, a metal plate made of copper, aluminum, or another may be inserted in the space formed between the third tip portion 23a and the insulating sheet 14. Even if the laser irradiation causes such melting that penetrates through the third tip portion 23a, the metal plate is able to prevent the melting from reaching the insulating sheet 14, which reduces the risk of damaging the insulating sheet 14. In the case of another technique such as ultrasonic welding or friction stir welding, the welding is performed while a predetermined jig is inserted into the space between the third tip portion 23a and the insulating sheet 14 and the first tip portion 13a and third tip portion 23a are pressed with a predetermined tool from the side where the first tip portion 13a is located.

Similarly, heat is applied by, for example, laser irradiation to the second tip portion 15a arranged over the insulating sheet 14 with the fourth tip portion 25a therebetween, from the side where the second tip portion 15a is located (from the lower side in FIG. 7). As a result, the second tip portion 15a and fourth tip portion 25a are melted and solidified at a second welding area 2b and are thereby welded to each other. For example, with this technique, the second terminal 15 of the semiconductor module 10B and the fourth terminal 25 of the capacitor 20B are welded to each other. In this example, the heat is applied by laser irradiation to weld (laser weld) the second terminal 15 and the fourth terminal 25 to each other. Alternatively, another technique such as ultrasonic welding or friction stir welding may be employed to apply heat from the side where the second tip portion 15a is located in order to weld the second terminal 15 and the fourth terminal 25 to each other.

In this connection, in the case of the laser welding, a metal plate made of copper, aluminum, or another may be inserted in the space formed between the fourth tip portion 25a and the insulating sheet 14. Even if the laser irradiation causes such melting that penetrates through the fourth tip portion 25a, the metal plate is able to prevent the melting from reaching the insulating sheet 14, which reduces the risk of damaging the insulating sheet 14. In the case of another technique such as ultrasonic welding or friction stir welding, the welding is performed while a predetermined jig is inserted into the space between the fourth tip portion 25a and the insulating sheet 14 and the second tip portion 15a and fourth tip portion 25a are pressed with a predetermined tool from the side where the second tip portion 15a is located.

Either the welding of the first terminal 13 and third terminal 23 or the welding of the second terminal 15 and fourth terminal 25 may be performed first, or both of them may be performed simultaneously.

The semiconductor module 10B and capacitor 20B are connected to each other as described above, so that the semiconductor device 1B as illustrated in FIG. 7 is obtained.

As described above, the semiconductor module 10B has the following configuration: the insulating sheet 14, first terminal 13, and second terminal 15 all extend to the outside of the resin case 11, the first tip portion 13a of the first terminal 13 is spaced apart from the first surface 14a of the insulating sheet 14, and the second tip portion 15a of the second terminal 15 is spaced apart from the second surface 14b of the insulating sheet 14. In the capacitor 20B, the third terminal 23 with the third tip portion 23a and the fourth terminal 25 with the fourth tip portion 25a are arranged so that the third tip portion 23a is inserted between the first tip portion 13a of the first terminal 13 and the insulating sheet 14 in the semiconductor module 10B and the fourth tip portion 25a is inserted between the second tip portion 15a of the second terminal 15 and the insulating sheet 14 in the semiconductor module 10B. The third terminal 23 and fourth terminal 25 of the capacitor 20B are inserted respectively between the first tip portion 13a and the insulating sheet 14 and between the second tip portion 15a and the insulating sheet 14 in a state of being spaced apart from the insulating sheet 14. Then, the first tip portion 13a and third tip portion 23a are welded to each other by heat applied from the opposite side from the insulating sheet 14, and the second tip portion 15a and fourth tip portion 25a are welded to each other by heat applied from the opposite side from the insulating sheet 14.

At this time, the first welding area 2a of the first tip portion 13a and third tip portion 23a is spaced apart from the insulating sheet 14, and the second welding area 2b of the second tip portion 15a and fourth tip portion 25a is spaced apart from the insulating sheet 14. Therefore, heat generated during the formation of the first welding area 2a and second welding area 2b is prevented from being transferred directly to the insulating sheet 14. This reduces the risk of damaging the insulating sheet 14 due to the heat during the welding. The reduction in the risk of damaging the insulating sheet 14 leads to preventing changes in the properties of the material of the insulating sheet 14, which prevents a deterioration in the insulation performance and accordingly a decrease in the withstand voltage. Thus, the above-described technique makes it possible to implement the high-performance, high-quality semiconductor device 1B.

Note that the shapes of the first terminal 13 and second terminal 15 illustrated in FIGS. 6 and 7, as well as the shapes of the third terminal 23 and fourth terminal 25 illustrated in FIG. 7, are not limited to those in the above-described example. As long as the third tip portion 23a is allowed to be arranged between the first tip portion 13a and the insulating sheet 14 and be welded to the first tip portion 13a in a state of being spaced apart from the insulating sheet 14 and also as long as the fourth tip portion 25a is allowed to be arranged between the second tip portion 15a and the insulating sheet 14 and be welded to the second tip portion 15a in a state of being spaced apart from the insulating sheet 14, various shapes may be employed for the first terminal 13 and second terminal 15 and for the third terminal and fourth terminal 25.

### Third Embodiment

A third embodiment will be described, which provides modifications of the above-described semiconductor module 10A.

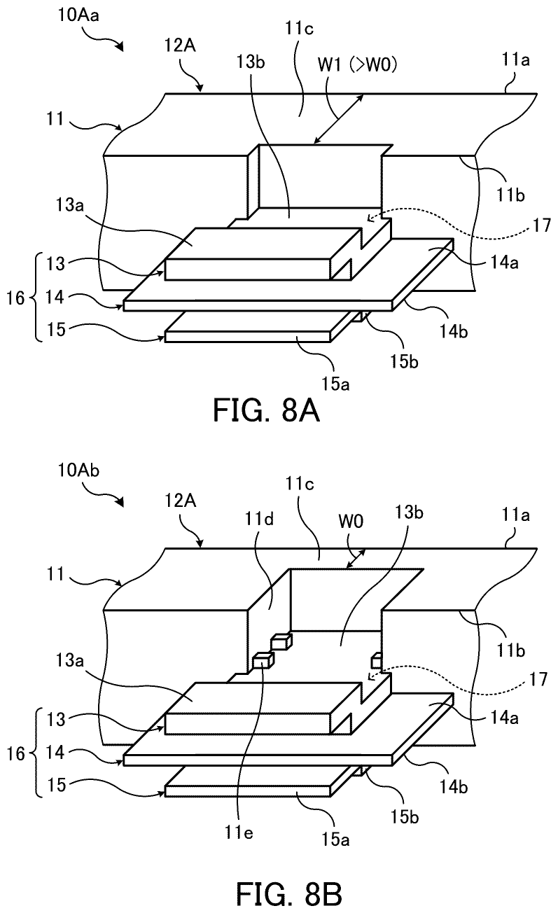

FIGS. 8A and 8B are views for describing examples of a semiconductor module according to the third embodiment. FIGS. 8A and 8B are schematic perspective views each illustrating a main part of an example semiconductor module or the like.

The semiconductor module 10Aa illustrated in FIG. 8A differs from the semiconductor module 10A described earlier in the first embodiment (FIGS. 4A and 4B) in that the pressing portion 11c, which presses the multilayer structure 16 formed of the first terminal 13, insulating sheet 14, and second terminal 15 against the terrace portion 17 of the resin case 11 (FIGS. 8A and 4B), has a larger width W1 (>W0).

In the multilayer structure 16, the first terminal 13, insulating sheet 14, and second terminal 15 are all arranged to extend to the outside of the resin case 11 beyond the outer edge 11b thereof. Therefore, if the width W0 of the pressing portion 11c that presses the multilayer structure 16 is relatively small, force generated by vibrations or other factors after connection with the capacitor 20A or the like may create separation in the multilayer structure 16, which increases the risk of damaging the above-described first welding area 2a and second welding area 2b. By contrast, the use of the pressing portion 11c with the relatively large width W1 to press the multilayer structure 16 effectively reduces the risk of causing separation in the multilayer structure 16 due to vibrations or others. This results in effectively reducing the risk of damaging the above-described first welding area 2a and second welding area 2b.

In addition, the semiconductor module 10Ab illustrated in FIG. 8B differs from the semiconductor module 10A (FIGS. 4A and 4B) described earlier in the first embodiment in that ribs 11e for pressing the multilayer structure 16 against the terrace portion 17 are provided on side walls 11d surrounding the terrace portion 17 of the resin case 11 (FIGS. 8A and 4B) where the multilayer structure 16 formed of the first terminal 13, insulating sheet 14, and second terminal 15 is arranged.

The ribs 11e provided in the semiconductor module 10Ab are one example of the pressing portion designed to press the multilayer structure 16 against the terrace portion 17. As in the above-described case, the use of these ribs 11e as the pressing portion effectively reduces the risk of causing separation due to vibration or other factors in the multilayer structure 16 formed of the first terminal 13, insulating sheet 14, and second terminal 15, which are arranged to extend to the outside of the resin case 11 beyond the outer edge 11b thereof, which results in effectively reducing the risk of damaging the above-described first welding area 2a and second welding area 2b.

In this connection, the pressing portion 11c with a relatively small width W0, as illustrated in FIG. 8B, may be combined with the ribs 11e as illustrated in FIG. 8B to press the multilayer structure 16. Alternatively, the pressing portion 11c with the relatively large width W1, as illustrated in FIG. 8A, may be combined with the ribs 11e as illustrated in FIG. 8B to press the multilayer structure 16.

This embodiment has described the modifications of, as an example, the semiconductor module 10A described earlier in the first embodiment, one modification being that the width of the pressing portion 11c is changed to the relatively large width W1 (FIG. 8A), the other modification being that the ribs 11e are added (FIG. 8B). Furthermore, the same modifications are also possible for the semiconductor module 10B described earlier in the second embodiment.

### Fourth Embodiment

A fourth embodiment will be described, which is an example of a method of manufacturing the above-described semiconductor device 1A and the like.

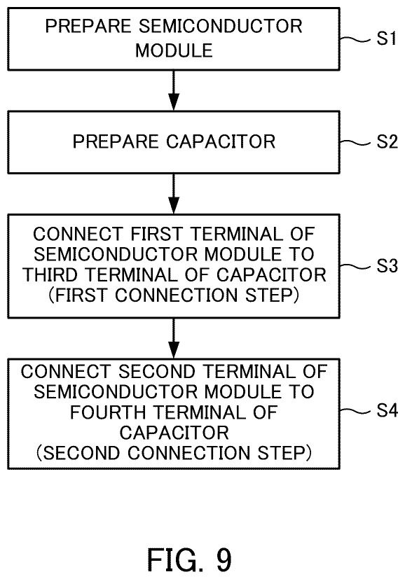

FIG. 9 is a view for describing an example of a semiconductor device manufacturing method according to the fourth embodiment.

For example, in manufacturing the semiconductor device 1A described earlier in the first embodiment (FIG. 5), the semiconductor module 10A is first prepared (step S1), and the capacitor 20A to be connected to the semiconductor module 10A is also prepared (step S2). Note that the order of steps S1 and S2 is interchangeable. Then, the semiconductor module 10A and capacitor 20A are arranged such that their terminal structure portion 12A and terminal structure portion 22A face each other, and then the first terminal 13 of the semiconductor module 10A is connected to the third terminal 23 of the capacitor 20A (step S3). Then, the second terminal 15 of the semiconductor module 10A is connected to the fourth terminal 25 of the capacitor 20A (step S4). Steps S3 and S4 may be performed in any order or simultaneously.

In the manufacturing of the semiconductor device 1A (FIG. 5), in the first connection step (step S3) of connecting the first tip portion 13a to the third tip portion 23a, the first tip portion 13a and third tip portion 23a are connected to each other in a state of being spaced apart from the first surface 14a of the insulating sheet 14. In the second connection step (step S4) of connecting the second tip portion 15a to the fourth tip portion 25a, the second tip portion 15a and fourth tip portion 25a are connected to each other in a state of being spaced apart from the second surface 14b of the insulating sheet 14. At this time, the tip surface of the first tip portion 13a and the tip surface of the third tip portion 23a are brought into contact with each other, and heat is applied by laser irradiation or the like from the opposite side from the insulating sheet 14, thereby welding the first terminal 13 and the third terminal 23 to each other. Similarly, the tip surface of the second tip portion 15a and the tip surface of the fourth tip portion 25a are brought into contact with each other, and heat is applied by laser irradiation or the like from the opposite side from the insulating sheet 14, thereby welding the second terminal 15 and the fourth terminal 25 to each other.

With this method, the semiconductor device 1A as described earlier in the first embodiment is manufactured. Note that the method may be employed for the semiconductor modules configured as described earlier in the third embodiment, in place of the semiconductor module 10A.

In the case of manufacturing the semiconductor device 1B (FIG. 7) as described earlier in the second embodiment, the semiconductor module 10B is first prepared (step S1), and the capacitor 20B to be connected to the semiconductor module 10B is also prepared (step S2). In this connection, the order of steps S1 and S2 is interchangeable. Then, the semiconductor module 10B and the capacitor 20B are arranged such that their terminal structure portion 12B and terminal structure portion 22B face each other, and the first terminal 13 of the semiconductor module 10B is connected to the third terminal 23 of the capacitor 20B (step S3). Then, the second terminal 15 of the semiconductor module 10B is connected to the fourth terminal 25 of the capacitor 20B (step S4). Steps S3 and S4 may be performed in any order or simultaneously.

In the manufacturing of the semiconductor device 1B (FIG. 5), in the first connection step (step S3) of connecting the first tip portion 13a to the third tip portion 23a, the first tip portion 13a and the third tip portion 23a are connected to each other in a state of being spaced apart from the first surface 14a of the insulating sheet 14. In the second connection step (step S4) of connecting the second tip portion 15a to the fourth tip portion 25a, the second tip portion 15a and the fourth tip portion 25a are connected to each other in a state of being spaced apart from the second surface 14b of the insulating sheet 14. At this time, the third tip portion 23a is arranged between the first surface 14a of the insulating sheet 14 and the first tip portion 13a, and heat is applied by laser irradiation or the like from the opposite side of the first tip portion 13a from the insulating sheet 14, thereby welding the first terminal 13 and the third terminal 23 to each other. The fourth tip portion 25a is arranged between the second surface 14b of the insulating sheet 14 and the second tip portion 15a, and heat is applied by laser irradiation or the like from the opposite side of the second tip portion 15a from the insulating sheet 14, thereby welding the second terminal 15 and the fourth terminal 25 to each other.

With the above method, the semiconductor device 1B as described earlier in the second embodiment is manufactured. In this connection, this method may be employed for the semiconductor modules configured as described earlier in the third embodiment, in place of the semiconductor module 10B.

According to one aspect, it is possible to reduce the risk of damaging an insulating sheet during the welding of a terminal of a semiconductor module.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
a resin case;
an insulating sheet having a first surface and a second surface opposite to the first surface, the insulating sheet extending from inside the resin case to outside;
a first terminal extending from inside the resin case to the outside, the first terminal being disposed on the first surface of the insulating sheet, except for a tip portion thereof that is spaced apart from the first surface in a thickness direction perpendicular to the first surface, the first terminal overlapping the insulating sheet in a plan view of the semiconductor module, the tip portion of the first terminal being a first tip portion; and
a second terminal extending from inside the resin case to the outside, the second terminal being disposed on the second surface of the insulating sheet, except for a tip portion thereof that is spaced apart from the second surface in the thickness direction, the second terminal overlapping the insulating sheet and the first terminal in the plan view, the tip portion of the second terminal being a second tip portion, wherein
the insulating sheet extends further outside than the first tip portion and the second tip portion.

2. The semiconductor module according to claim 1, wherein the first tip portion and the second tip portion overlap each other in the plan view.

3. The semiconductor module according to claim 1, wherein
the first terminal further includes a first extending portion extending from inside the resin case to the first tip portion and being in contact with the first surface, and
the second terminal further includes a second extending portion extending from inside the resin case to the second tip portion and being in contact with the second surface.

4. The semiconductor module according to claim 1, wherein the resin case includes
a terrace portion on which the first terminal, the second terminal, and the insulating sheet are disposed, and
a pressing portion pressing the first terminal, the second terminal, and the insulating sheet disposed against the terrace portion.

5. A semiconductor device, comprising:
a semiconductor module, including
an insulating sheet having a first surface and a second surface opposite to the first surface, the insulating sheet extending from inside the resin case to outside;
a first terminal extending from inside the resin case to the outside, the first terminal being disposed on the first surface of the insulating sheet, except for a tip portion thereof that is spaced apart from the first surface in a thickness direction perpendicular to the first surface, the first terminal overlapping the insulating sheet in a plan view of the semiconductor module, the tip portion of the first terminal being a first tip portion; and
a second terminal extending from inside the resin case to the outside, the second terminal being disposed on the second surface of the insulating sheet, except for a tip portion thereof that is spaced apart from the second surface in the thickness direction, the second terminal overlapping the insulating sheet and the first terminal in the plan view, the tip portion of the second terminal being a second tip portion, wherein
the insulating sheet extends further outside than the first tip portion and the second tip portion; and
a capacitor including two terminals, tip portions thereof being respectively:
a third tip portion connected to the first tip portion and spaced apart from the first surface in the thickness direction, and
a fourth tip portion connected to the second tip portion and being spaced apart from the second surface in the thickness direction.

6. The semiconductor device according to claim 5, wherein
the first tip portion and the third tip portion are connected without overlapping each other in the plan view, and
the second tip portion and the fourth tip portion are connected without overlapping each other in the plan view.

7. The semiconductor device according to claim 5, wherein
the third tip portion and the first tip portion overlap each other in the plan view, and
the fourth tip portion and the second tip portion overlap each other in the plan view.

8. The semiconductor device according to claim 5, wherein
the first tip portion and the third tip portion have a first welding area therebetween, and
the second tip portion and the fourth tip portion have a second welding area therebetween.

9. A method of manufacturing a semiconductor device including:
a semiconductor module, including
a resin case,
an insulating sheet having a first surface and a second surface opposite to the first surface, the insulating sheet extending from inside the resin case to outside;
a first terminal extending from inside the resin case to the outside, the first terminal being disposed on the first surface of the insulating sheet, except for a tip portion thereof that is spaced apart from the first surface in a thickness direction perpendicular to the first surface, the first terminal overlapping the insulating sheet in a plan view of the semiconductor module, the tip portion of the first terminal being a first tip portion; and
a second terminal extending from inside the resin case to the outside, the second terminal being disposed on the second surface of the insulating sheet, except for a tip portion thereof that is spaced apart from the second surface in the thickness direction, the second terminal overlapping the insulating sheet and the first terminal in the plan view, the tip portion of the second terminal being a second tip portion, wherein
the insulating sheet extends further outside than the first tip portion and the second tip portion; and
a capacitor including two terminals, tip portions thereof being respectively:
a third tip portion connected to the first tip portion and spaced apart from the first surface in the thickness direction, and
a fourth tip portion connected to the second tip portion and being spaced apart from the second surface in the thickness direction,
the method comprising:
connecting the first tip portion and the third tip portion to each other while maintaining the first tip portion and the third tip portion to be spaced apart from the first surface in the thickness direction; and
connecting the second tip portion and the fourth tip portion to each other while maintaining the second tip portion and the fourth tip portion to be spaced apart from the second surface in the thickness direction.

10. The method of manufacturing the semiconductor device according to claim 9, wherein
the connecting the first tip portion and the third tip portion to each other includes arranging the first tip portion and the third tip portion not to overlap each other in the plan view, and
the connecting the second tip portion and the fourth tip portion to each other includes arranging the second tip portion and the fourth tip portion not to overlap each other in the plan view.

11. The method of manufacturing the semiconductor device according to claim 9, wherein
the connecting the first tip portion and the third tip portion to each other includes arranging the third tip portion and the first tip portion to overlap each other in the plan view, and
the connecting the second tip portion and the fourth tip portion to each other includes arranging the fourth tip portion and the second tip portion to overlap each other in the plan view.

12. The method of manufacturing the semiconductor device according to claim 9, wherein
the connecting the first tip portion and the third tip portion to each other includes welding the first tip portion and the third tip portion to each other by applying heat from a side of the first tip portion that is opposite to a side of the first tip portion where the first surface is located, and
the connecting the second tip portion and the fourth tip portion to each other includes welding the second tip portion and the fourth tip portion to each other by applying heat from a side of the second tip portion that is opposite to a side of the second tip portion where the second surface is located.
